(19) United States
(12) Patent Application Publication
(10) Pub. No.: US 2025/0287571 A1
(43) Pub. Date: Sep. 11, 2025

(54) SEMICONDUCTOR DEVICE

(71) Applicant: Samsung Electronics Co., Ltd., Suwon-si (KR)

(72) Inventors: Junsoo Kim, Suwon-si (KR); Sangho Lee, Suwon-si (KR); Jeonghoon Oh, Suwon-si (KR); Sungho Jang, Suwon-si (KR)

(21) Appl. No.: 18/807,159

(22) Filed: Aug. 16, 2024

(30) Foreign Application Priority Data
Mar. 5, 2024 (KR) 10-2024-0031458

(51) Int. Cl. H10B 12/00; H01L 29/66; H01L 29/78

(52) U.S. Cl. CPC H10B 12/482; H10B 12/05; H10B 12/315; H10B 12/485; H10B 12/50; H10D 30/025; H10D 30/63

(57) ABSTRACT

A semiconductor device includes a substrate, a bit line extending in a first direction on the substrate, a vertical channel pattern on the bit line, a gate electrode adjacent to the vertical channel pattern in the first direction, a first work function adjustment pattern on the gate electrode, and a first contact on the vertical channel pattern. The first work function adjustment pattern is adjacent to one end of the vertical channel pattern in the first direction. The first work function adjustment pattern includes a metal material different from that of the gate electrode.

### CROSS-REFERENCE TO RELATED APPLICATIONS

This U.S. non-provisional patent application claims priority under 35 U.S.C. § 119 to Korean Patent Application No. 10-2024-0031458, filed on Mar. 5, 2024, in the Korean Intellectual Property Office, the entire contents of which are hereby incorporated by reference.

### FIELD OF THE INVENTION

The inventive concept relates to a semiconductor device and a method of manufacturing the same, and more specifically relates to a semiconductor device including vertical channel transistors.

### BACKGROUND OF THE INVENTION

As a semiconductor device is scaled down, it may be necessary to develop a fabrication technology capable of increasing integration density of the semiconductor device and improving an operation speed and a yield. Accordingly, a transistor with an oxide semiconductor channel has been proposed to improve integration density, electrical resistance properties, and current driving ability of the transistor.

### SUMMARY

Embodiments of the inventive concept is to provide a semiconductor device with improved electrical characteristics and a method of manufacturing the same.

Problems to be solved by the inventive concept are not limited to the problems mentioned above, and embodiments of the inventive concept may be applied to other problems not mentioned and will be clearly understood by those skilled in the art from the description below.

A semiconductor device according to some embodiments of the inventive concept may include a substrate, a bit line extending in a first direction on the substrate, a vertical channel pattern on the bit line, a gate electrode adjacent to the vertical channel pattern in the first direction, a first work function adjustment pattern on the gate electrode, and a first contact on the vertical channel pattern, wherein the first work function adjustment pattern is adjacent to one end of the vertical channel pattern in the first direction, and the first work function adjustment pattern includes a metal material different from that of the gate electrode.

A semiconductor device according to some embodiments of the inventive concept may include a substrate, a bit line on the substrate, a bit line contact on the bit line, vertical channel patterns and a gate structure on the bit line, the gate structure being disposed between the vertical channel patterns, a first work function adjustment pattern on the gate structure, and a storage node contact on the vertical channel pattern, wherein the gate structure includes a gate electrode, the first work function adjustment pattern has a first work function, the bit line contact and the storage node contact have a second work function, the gate electrode has a third work function, and a value of the first work function is between those of the second work function and the third work function.

A semiconductor device according to some embodiments of the inventive concept may include a substrate, a bit line on the substrate, a bit line contact on the bit line, a gate structure, a work function adjustment pattern and vertical channel patterns on the bit line contact, the work function adjustment pattern including a first work function adjustment pattern on a lower portion of the gate structure and a second work function adjustment pattern on an upper portion of the gate structure that is opposite the lower portion, a back gate structure extending into the bit line contact on the bit line, a storage node contact on one of the vertical channel patterns, a landing pad on the storage node contact, and a capacitor on the landing pad, wherein the gate structure includes a gate electrode, the first work function adjustment pattern and the second work function adjustment pattern are adjacent to the bit line contact and the storage node contact, respectively, the work function adjustment pattern has a work function of about 4.15 eV to about 4.3 eV, the bit line contact and the storage node contact have a work function of about 3.9 eV to about 4.1 eV, and the gate electrode has a work function of about 4.4 eV to about 4.6 eV.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a block diagram showing a semiconductor device according to some embodiments of the inventive concept.

FIGS. 2 and 3 are perspective views briefly showing semiconductor devices according to some embodiments of the inventive concept.

FIG. 4 is a plan view of a semiconductor device according to some embodiments of the inventive concept.

FIG. 5 is a cross-sectional view taken along line A-A′ in FIG. 4.

FIG. 6 is a cross-sectional view taken along line B-B′ in FIG. 4.

FIG. 7 is a cross-sectional view taken along line A-A′ of FIG. 4 to illustrate a semiconductor device according to another embodiment of the inventive concept.

FIG. 8 is a cross-sectional view taken along line A-A′ of FIG. 4 to illustrate semiconductor devices according to other embodiments of the inventive concept.

FIGS. 9A, 9B, 9C, 9D, 9E, 9F, 9G, and 9H are cross-sectional views showing a manufacturing process of a semiconductor device according to some embodiments of the inventive concept.

FIGS. 10A and 10B are cross-sectional views showing portion of a manufacturing process of a semiconductor device according to some embodiments of the inventive concept.

FIGS. 11A and 11B are cross-sectional views showing portion of a manufacturing process of a semiconductor device according to some embodiments of the inventive concept.

### DETAILED DESCRIPTION

Hereinafter, the inventive concepts will be described in detail by explaining embodiments of the inventive concept with reference to the accompanying drawings. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

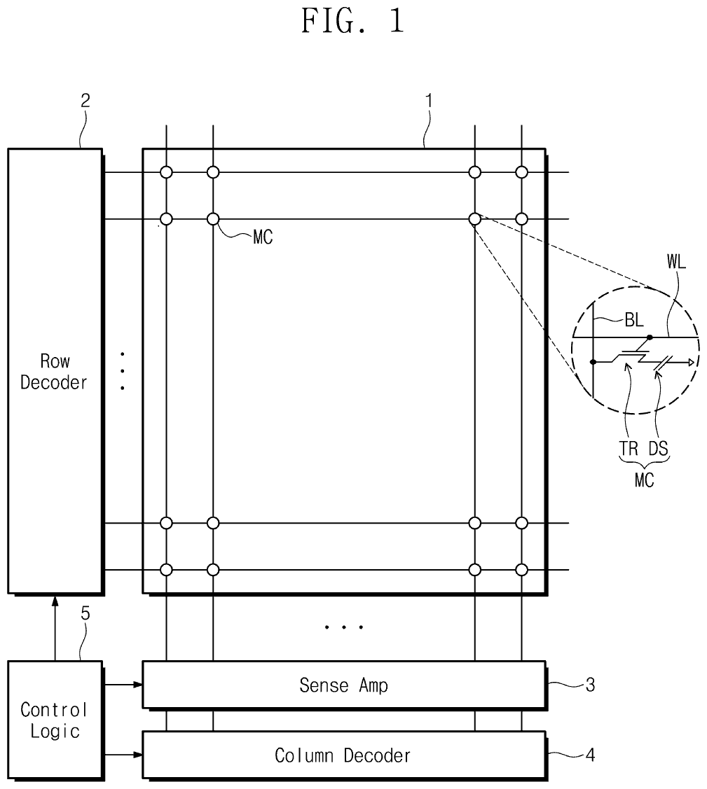

FIG. 1 is a block diagram showing a semiconductor device according to some embodiments of the inventive concept.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC three-dimensionally arranged. Each of the memory cells MC may be provided between and connected to a word line WL and a bit line BL, which are disposed to cross each other. Each of the memory cells MC may include a selection element TR and a data storage element DS. The selection element TR and the data storage element DS may be electrically connected to each other. The selection element TR may be connected to both a word line WL and a bit line BL. In other words, the selection element TR may be provided at a point where the word line WL and the bit line BL intersect each other.

The selection element TR may include a transistor. The selection element TR may include a field effect transistor. The data storage element DS may include a capacitor, a magnetic tunnel junction pattern, or a variable resistor. For example, a gate terminal of the transistor that is the selection element TR may be connected to the word line WL, and source/drain terminals of the transistor may be connected to the bit line BL and the data storage element DS, respectively.

The row decoder 2 may decode an externally input address and select one of the word lines WL of the memory cell array 1. The address decoded in the row decoder 2 may be provided to a row driver (not shown), and the row driver may provide a certain voltage to a selected word line WL and a unselected word lines WL in response to control of a control circuits, respectively.

The sense amplifier 3 may detect and amplify a voltage difference between a selected bit line BL and a reference bit line in response to the address decoded from the column decoder 4 and output the amplified voltage difference.

The column decoder 4 may provide a data transmission path between the sense amplifier 3 and an external device (e.g., a memory controller). The column decoder 4 may decode an externally input address and select one of the bit lines BL. The control logic 5 may generate a control signal that controls operation of writing or reading data into the memory cell array 1.

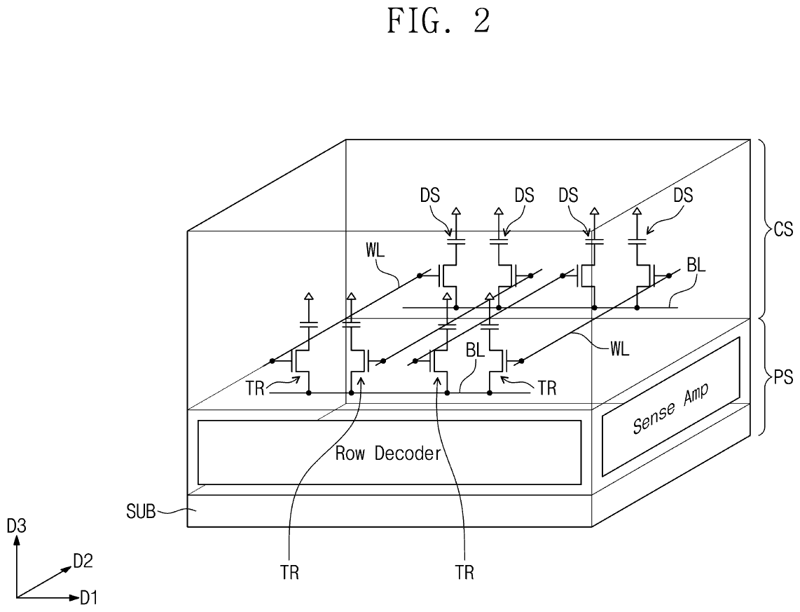

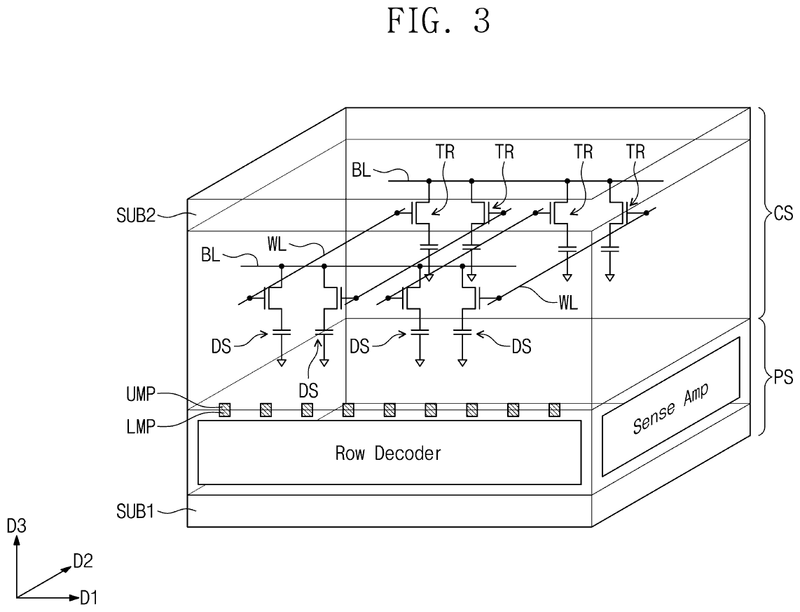

FIGS. 2 and 3 are perspective views briefly showing semiconductor devices according to some embodiments.

Referring to FIGS. 2 and 3, a semiconductor device may include a peripheral circuit structure PS and a cell array structure CS connected to the peripheral circuit structure PS.

The peripheral circuit structure PS may include a core and peripheral circuits formed on a substrate SUB. The core and peripheral circuits may include the row and column decoders 2 and 4, the sense amplifier 3 and the control logic 5 described with reference to FIG. 1.

The cell array structure CS may include a memory cell array 1 (in FIG. 1) including memory cells MC (in FIG. 1A) arranged two-dimensionally or three-dimensionally. As described above, each of the memory cells MC (in FIG. 1) may include a selection element TR and a data storage element DS.

In some embodiments, the selection element TR of each memory cell MC (in FIG. 1) may include a vertical channel transistor VCT. The vertical channel transistor VCT may include a channel whose lengthwise direction is perpendicular to an upper surface of the substrate SUB. The data storage element DS of each memory cell MC (in FIG. 1) may include a capacitor.

In the embodiment according to FIG. 2, the peripheral circuit structure PS may be provided on the substrate SUB. Alternatively, the cell array structure CS may be provided on the peripheral circuit structure PS.

In the embodiment according to FIG. 3, the peripheral circuit structure PS may be provided on a first substrate SUB1, and the cell array structure CS may be provided on a second substrate SUB2. The first substrate SUB1 and the second substrate SUB2 may face each other.

First metal pads LMP may be provided at the uppermost surface of the peripheral circuit structure PS. The first metal pads LMP may be electrically connected to the core and peripheral circuits 2, 3, 4, and 5 (in FIG. 1).

Second metal pads UMP may be provided at the lowermost surface of the cell array structure CS. The second metal pads UMP may be electrically connected to the memory cell array 1 (in FIG. 1). The second metal pads UMP may be in direct contact with and may bond to the first metal pads LMP of the peripheral circuit structure PS.

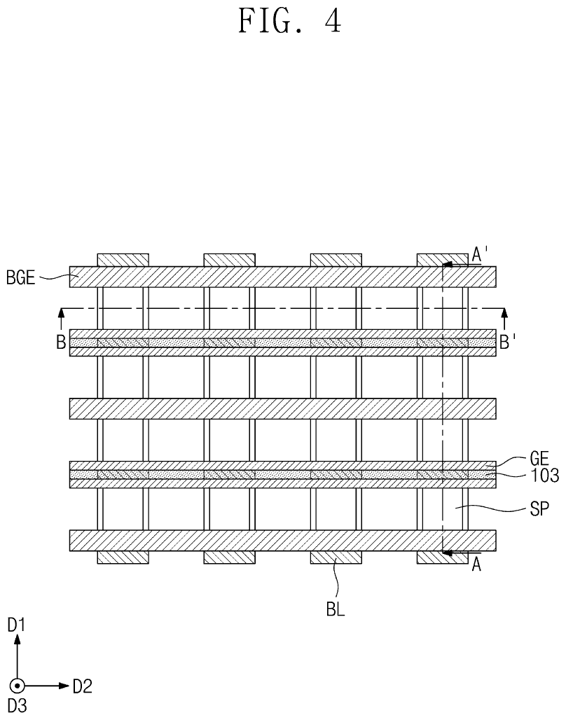

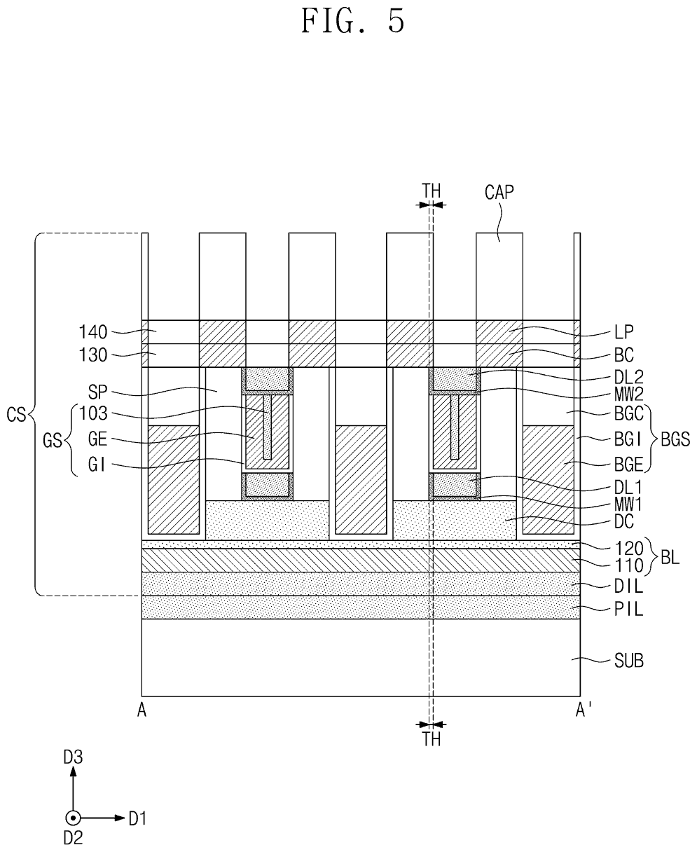

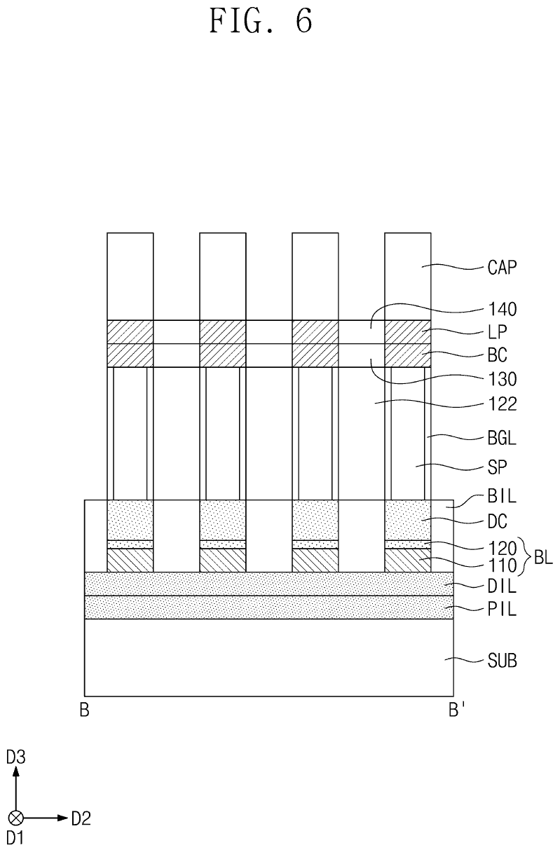

FIG. 4 is a plan view of a semiconductor device according to some embodiments of the inventive concept. FIG. 5 is a cross-sectional view taken along line A-A′ in FIG. 4. FIG. 6 is a cross-sectional view taken along line B-B′ in FIG. 4.

Referring to FIGS. 4 to 6, a peripheral circuit insulating layer PIL may be provided on a substrate SUB. The substrate SUB may have a shape of a plate or may otherwise include a planar surface extending along a plane defined by a first direction D1 and a second direction D2.

In this specification, the first direction D1 is defined as a direction parallel to an upper surface of the substrate SUB. The second direction D2 is parallel to the upper surface of the substrate SUB and is defined as a direction perpendicular to the first direction D1. A third direction D3 is defined as a direction perpendicular to the upper surface of the substrate SUB, e.g., a vertical direction.

A peripheral circuit insulating layer PIL may include an insulating material. As an example, the peripheral circuit insulating layer PIL may include nitride. In some embodiments of the inventive concept, the peripheral circuit structure PS described with reference to FIG. 2 may be provided between the substrate SUB and the peripheral circuit insulating layer PIL. Additionally, in some embodiments of the inventive concept, an integrated circuit such as a logic element may be provided between the substrate SUB and the peripheral circuit insulating layer PIL.

The cell array structure CS may be provided on the peripheral circuit insulating layer PIL. The cell array structure CS may include memory cells including vertical channel transistors. The cell array structure CS includes a bit line BL, a bit line contact DC, a back gate structure BGS, a gate structure GS, first and second work function adjustment patterns MW1 and MW2, a vertical channel patterns SP, a storage node contacts BC, and capacitors CAP.

A lower insulating layer DIL may be provided on the peripheral circuit insulating layer PIL. For example, the peripheral circuit insulating layer PIL and the lower insulating layer DIL may be bonded through a wafer bonding process.

The bit line BL may be provided on the lower insulating layer DIL. The bit line BL may extend in the first direction B1 and a plurality of bit lines BL may be provided to spaced apart from each other in the second direction D2. The bit line BL may include a metal pattern 110 and a polysilicon pattern 120 sequentially stacked on the lower insulating layer DIL. The metal pattern 110 may include conductive metal nitride (e.g., titanium nitride, tantalum nitride, etc.) and metal (e.g., tungsten, titanium, tantalum, etc.).

The bit line contact DC may be provided on the bit line BL. The bit line contact DC may also be referred to as a first contact DC in this specification. The bit line contact DC may include a conductive material. The bit line contact DC may have a first work function. For example, the first work function may be 3.9 eV to 4.1 eV. The work functions of patterns or components as described herein (or values thereof) may depend, for example, on the constituent materials and/or other characteristics thereof (such as, but not limited to, surface characteristics and doping level).

A bit line insulating pattern BIL may be provided on the lower insulating layer DIL (refer to FIG. 6). The bit line insulation patterns BIL may be provided in plural. The bit line insulation patterns BIL may be arranged to be spaced apart from each other in the second direction D2 with the bit line BL and the bit line contact DC interposed therebetween.

The back gate structure BGS may be provided on the bit line BL by penetrating or extending into the bit line contact DC. The back gate structure BGS may be provided, thereby improving electrical reliability by minimizing variations in the threshold voltage of the transistor including the vertical channel pattern SP, which will be described later. A plurality of back gate structures BGS may be provided to be spaced apart from each other in the first direction D1. The back gate structure BGS may include a back gate electrode BGE, a back gate capping pattern BGC, and a back gate insulating pattern BGI.

The back gate electrode BGE may be disposed below the back gate structure BGS. For example, the back gate electrode BGE may include a conductive metal nitride (e.g., titanium nitride, tantalum nitride, etc.), a metal (e.g., tungsten, titanium, tantalum, etc.), a conductive metal silicide, a conductive metal oxide, or a combination thereof. The back gate electrode BGE may have a second work function. For example, the second work function may be 4.4 eV to 4.6 eV.

A back gate capping pattern BGC may be provided on the back gate electrode BGE. For example, the back gate capping pattern BGC may include an insulating material such as silicon nitride.

The back gate insulating pattern BGI may surround a lower surface and a side surface of the back gate electrode BGE and a side surfaces of the back gate capping pattern BGC. The term “surround” (or “cover” or “fill”) as may be used herein may not require completely surrounding or covering or filling the described elements or layers, but may, for example, refer to partially surrounding or covering or filling the described elements or layers, for example, with discontinuities throughout. A lower portion of the back gate insulating pattern BGI may be in contact with an upper surface of a polysilicon pattern 120. For example, the back gate insulating pattern BGI may include at least one of silicon oxide, a high dielectric material, or a combination thereof.

A first work function adjustment pattern MW1 and a first dielectric pattern DL1 may be provided on the bit line contact DC. The first work function adjustment pattern MW1 and the first dielectric pattern DL1 may be provided in plural. The first work function adjustment patterns MW1 may be arranged to be spaced apart from each other in the first direction D1. The first dielectric patterns DL1 may be arranged to be spaced apart from each other in the first direction D1. The first work function adjustment pattern MW1 may be in contact with the bit line contact DC. The first dielectric pattern DL1 may be provided on the first work function adjustment pattern MW1, and the first work function adjustment pattern MW1 may surround a lower surface and side surfaces of the first dielectric pattern DL1. A thickness TH of the first work function adjustment pattern MW1 may be 3 Å to 10 Å.

The first work function adjustment pattern MW1 may include a metal material different from that of a gate electrode GE, which will be described later. For example, the first work function adjustment pattern MW1 may include at least one of aluminum oxide and lanthanum oxide. The first work function adjustment pattern MW1 may have a third work function. The third work function may be smaller than the second work function. The third work function may be an intermediate value between respective values of the first work function and the second work function. For example, the third work function may be 4.15 eV to 4.3 eV. For example, the first dielectric pattern DL1 may include a dielectric material such as hafnium oxide or zirconium oxide.

The gate structure GS may be provided on the first work function adjustment pattern MW1. A plurality of gate structures GS may be provided to be spaced apart from each other in the first direction D1. The gate structure GS may include a gate electrode GE, a gate dielectric layer 103, and a gate insulating pattern GI.

The gate electrode GE may be provided on the first work function adjustment pattern MW1. The gate electrode GE may also be called a front gate. For example, the gate electrode GE may have a shape similar to a “U” when viewed in a cross-sectional view. The gate electrode GE may include, for example, a conductive metal nitride (e.g., titanium nitride, tantalum nitride, etc.), a metal (e.g., tungsten, titanium, tantalum, etc.), a conductive metal silicide, a conductive metal oxide, or a combination thereof. The gate electrode GE may have a second work function. For example, the second work function may be 4.4 eV to 4.6 eV.

A gate dielectric layer 103 may be provided in the gate electrode GE. The gate electrode GE may surround a side surface and a lower surface of the gate dielectric layer 103. For example, the gate dielectric layer 103 may include a dielectric material such as hafnium oxide or zirconium oxide.

The gate insulating pattern GI may surround a lower surface and a side surface of the gate electrode GE. A lower portion of the gate insulating pattern GI may be in contact with the first work function adjustment pattern MW1 and the first dielectric pattern DL1. An upper portion of the gate insulating pattern GI may be in contact with the second work function adjustment pattern MW2. Unlike shown, according to some embodiments of the inventive concept, the gate insulating pattern GI may not surround the lower surface of the gate electrode GE. For example, the gate insulating pattern GI may include at least one of silicon oxide, a high dielectric material, or a combination thereof.

A second work function adjustment pattern MW2 and a second dielectric pattern DL2 may be provided on the gate structure GS. The second work function adjustment pattern MW2 and the second dielectric pattern DL2 may be provided in plural to be spaced apart from each other in the first direction D1. The second dielectric pattern DL2 may be provided on the second work function adjustment pattern MW2. The second work function adjustment pattern MW2 may be in contact with an upper portion of the gate insulating pattern GI, an upper surface of the gate electrode GE, and an upper surface of the gate dielectric layer 103. A thickness TH of the second work function adjustment pattern MW2 may be 3 Å to 10 Å.

The second work function adjustment pattern MW2 may include a metal material different from that of the gate electrode GE. For example, the second work function adjustment pattern MW2 may include at least one of aluminum oxide and lanthanum oxide. The second work function adjustment pattern MW2 may have a third work function. For example, the third work function may be 4.15 eV to 4.3 eV. For example, the second dielectric pattern DL2 may include a dielectric material such as hafnium oxide or zirconium oxide.

Vertical channel patterns SP may be provided on the bit line contact DC. A plurality of vertical channel patterns SP may be provided to be spaced apart from each other in the first direction D1 and the second direction D2. The back gate structure BGS and the gate structure GS may be disposed between a pair of vertical channel patterns SP, respectively. In this case, the above-described first work function adjustment pattern MW1 and the second work function adjustment pattern MW2 may each be disposed adjacent to one end of the vertical channel pattern SP in the first direction D1. Specifically, one side or sidewall of each of the vertical channel patterns SP may be in contact with the first work function adjustment pattern MW1, the gate insulating pattern GI, and the second work function adjustment pattern MW2. The other side or opposing sidewall of each of the vertical channel patterns SP may be provided on one side of the back gate structure BGS and may be in contact with the back gate insulating pattern BGI.

The vertical channel pattern SP and the bit line contact DC may form ohmic contact. A lower portion of the vertical channel pattern SP may function as a first source/drain region, an upper portion of the vertical channel pattern SP may function as a second source/drain, and a portion of the vertical channel pattern SP between two source/drain regions may function as a channel. The vertical channel patterns SP may include a single crystal semiconductor material. As an example, the vertical channel patterns SP may include single crystal silicon.

A channel insulation pattern 122 may be provided on the bit line insulation pattern BIL (refer to FIG. 6). The channel insulation pattern 122 may be provided between vertical channel patterns SP spaced apart from each other in the second direction D2. For example, the channel insulation pattern 122 may include an insulating material such as silicon oxide, silicon nitride, silicon oxynitride, and/or a low dielectric material.

A storage node contact BC may be provided on an upper surface of the vertical channel pattern SP. The storage node contact BC may also be referred to as a second contact BC in this specification. The storage node contact BC and vertical channel pattern SP may overlap vertically. A plurality of storage node contacts BC may be provided to be spaced apart from each other in the first direction D1 and the second direction D2. The storage node contact BC may include a conductive material. The storage node contact BC and vertical channel pattern SP may form ohmic contact. The storage node contact BC may have a first work function. For example, the first work function may be 3.9 eV to 4.1 eV.

A landing pad LP may be provided on the storage node contact BC. The storage node contact BC may electrically connect the vertical channel pattern SP and the landing pad LP. A plurality of landing pads LP may be provided to be spaced apart from each other in the first direction D1 and the second direction D2, and may be arranged in various shapes such as a matrix shape, a zigzag shape, or a honeycomb shape. When viewed in a two-dimensional perspective view, each of the landing pads LP may have various shapes, such as circular, oval, rectangular, square, diamond, or hexagonal shapes.

The landing pad LP may include a conductive material. The landing pad LP may be formed of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

A first upper insulating layer 130 may be provided on the back gate structure BGS. Specifically, the first upper insulating layer 130 may be provided between the storage node contacts BC to space or provide spacings between the storage node contacts BC.

A second upper insulating layer 140 may be provided on the first upper insulating layer 130. The second upper insulating layer 140 may be provided between the landing pads LP to separate the landing pads LP.

The first and second upper insulating layers 130 and 140 may include an insulating material. According to some embodiments, the first and second upper insulating layers 130 and 140 may be a multilayer including a plurality of insulating layers.

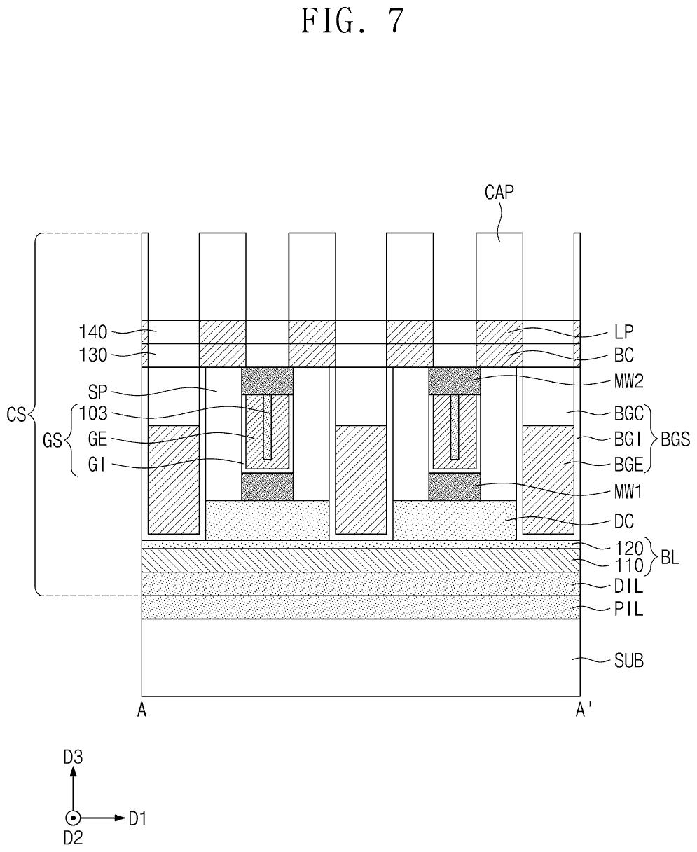

A capacitor CAP may be provided on the landing pad LP. A plurality of capacitors CAP may be provided. The plurality of capacitors CAP may be spaced apart from each other in the first and second directions D1 and D2. Each of the capacitors CAP may be connected to the vertical channel pattern SP through a corresponding landing pad LP and storage node contact BC. The capacitor CAP may include a lower electrode, a dielectric layer, and an upper electrode, and may include various structures and/or materials capable of storing data. FIG. 7 is a cross-sectional view taken along line A-A′ of FIG. 4 to illustrate a

semiconductor device according to another embodiment of the inventive concept. Descriptions that overlap with those of FIG. 5 will be omitted.

Referring to FIG. 7, the first work function adjustment pattern MW1 may be provided between the bit line contact DC and the gate structure GS. Specifically, a lower surface of the first work function adjustment pattern MW1 may be in contact with an upper surface of the bit line contact DC. An upper surface of the first work function adjustment pattern MW1 may be in contact with a lower portion of the gate insulating pattern GI.

A second work function adjustment pattern MW2 may be provided on the gate structure GS. Specifically, the lower surface of the second work function adjustment pattern MW2 may be in contact with an upper surface of the gate insulating pattern GI, an upper surface of the gate dielectric layer 103, and an upper surface of the gate electrode GE. A level of the upper surface of the second work function adjustment pattern MW2 and a level of the upper surface of the vertical channel pattern SP may be substantially the same that is, substantially coplanar. The first work function adjustment pattern MW1 and the second work function adjustment pattern MW2 may include polysilicon doped with impurities (e.g., n-type). The first work function adjustment pattern MW1 and the second work function adjustment pattern MW2 may have a third work function. For example, the third work function may be 4.15 eV to 4.3 eV.

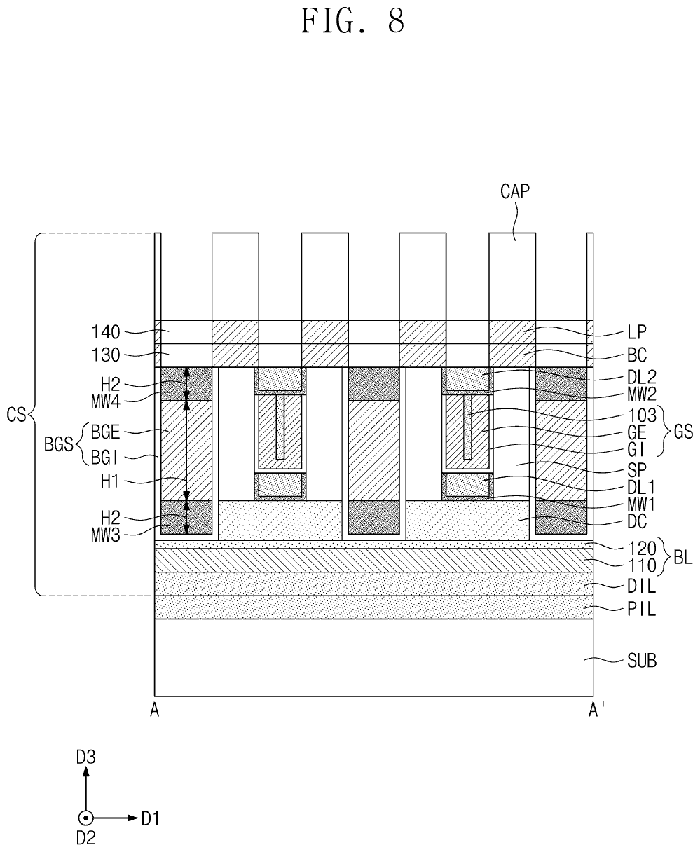

FIG. 8 is a cross-sectional view taken along line A-A′ of FIG. 4 to illustrate semiconductor devices according to other embodiments of the inventive concept. Descriptions that overlap with those of FIG. 5 will be omitted.

Referring to FIG. 8, third and fourth work function adjustment patterns MW3 and MW4 may be provided on lower and upper surfaces of the back gate electrode BGE, respectively. Specifically, the lower surface of the third work function adjustment pattern MW3 may be in contact with the lower surface of the back gate insulating pattern BGI. The upper surface of the fourth work function adjustment pattern MW4 may be in contact with the lower surface of the first upper insulating layer 130.

The back gate electrode BGE and the third and fourth work function adjustment patterns MW3 and MW4 may have a first height H1 and a second height H2 in the third direction D3, respectively. The first height H1 may be 3 to 5 times the second height H2. As an example, the first height H1 may be 100 nm to 120 nm. The second height H2 may be 20 nm to 40 nm.

The third and fourth work function adjustment patterns MW3 and MW4 may include polysilicon doped with impurities (e.g., n-type). The third and fourth work function adjustment patterns MW3 and MW4 may have a third work function. For example, the third work function may be 4.15 eV to 4.3 eV.

The semiconductor device according to an embodiment of the inventive concept may include a work function adjustment pattern between the gate electrode and the bit line contact, and a work function adjustment pattern between the gate electrode and the storage node contact. The work function of the work function adjustment patterns (e.g., the third work function) may be a value between the values of the work function of the gate electrode (e.g., the second work function) and the work function of the bit line contact and the storage node contact (e.g., the first work function). Accordingly, metal resistance between the gate electrode and the bit line contact and between the gate electrode and the storage node contact may be reduced or alleviated, and leakage current of the gate electrode may be reduced. As a result, electrical characteristics and reliability of semiconductor devices may be improved.

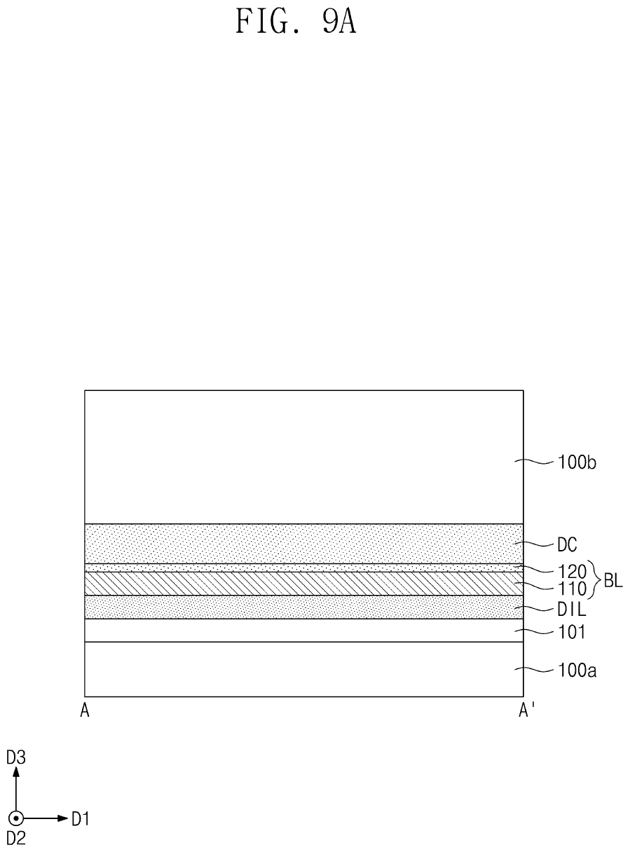

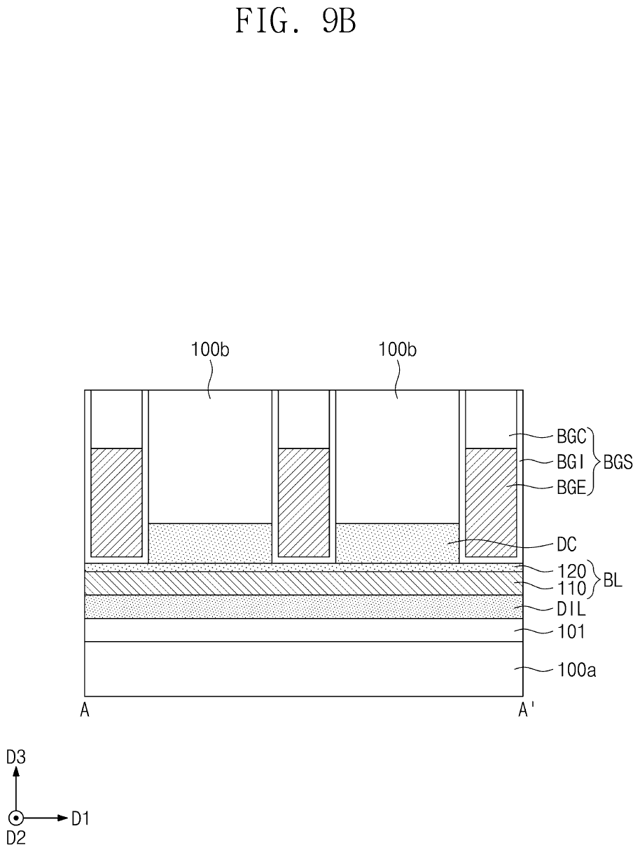

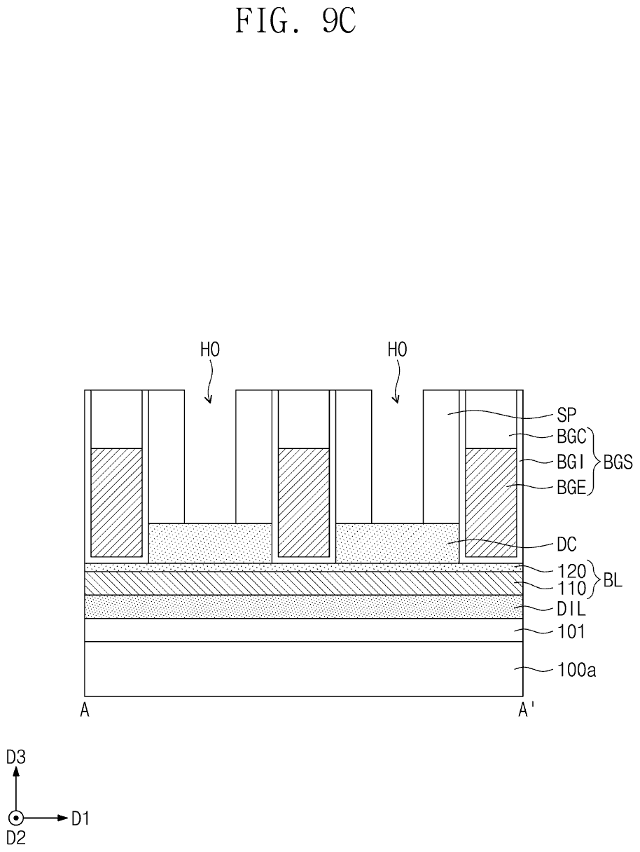

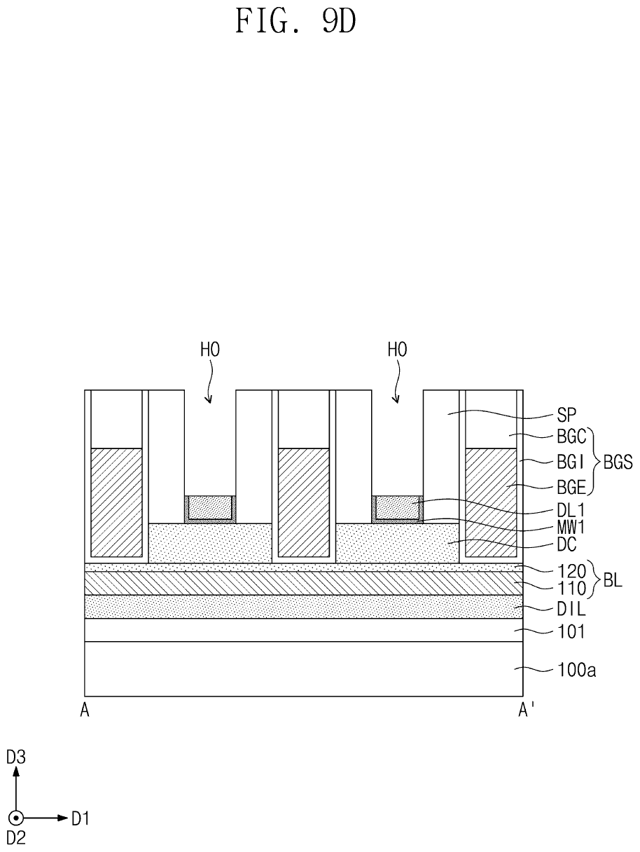

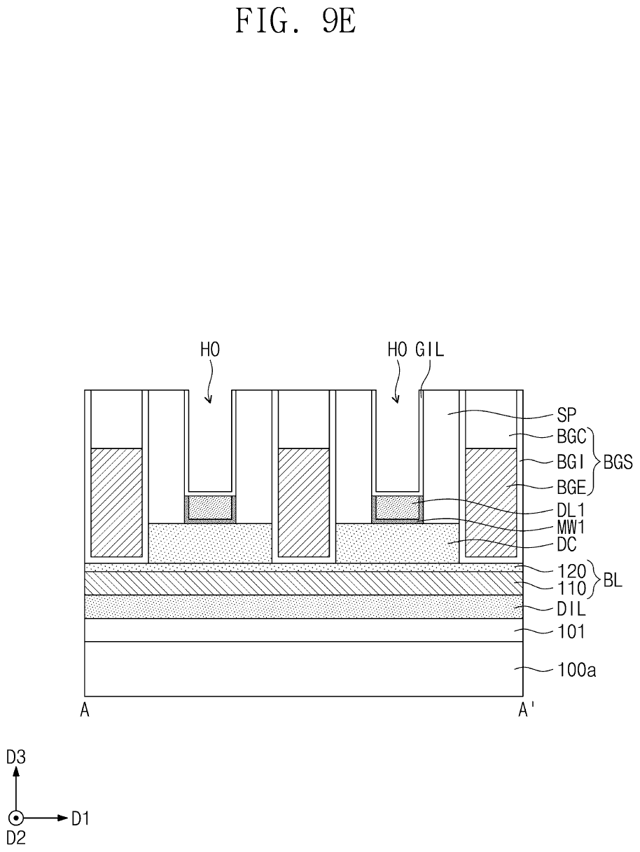

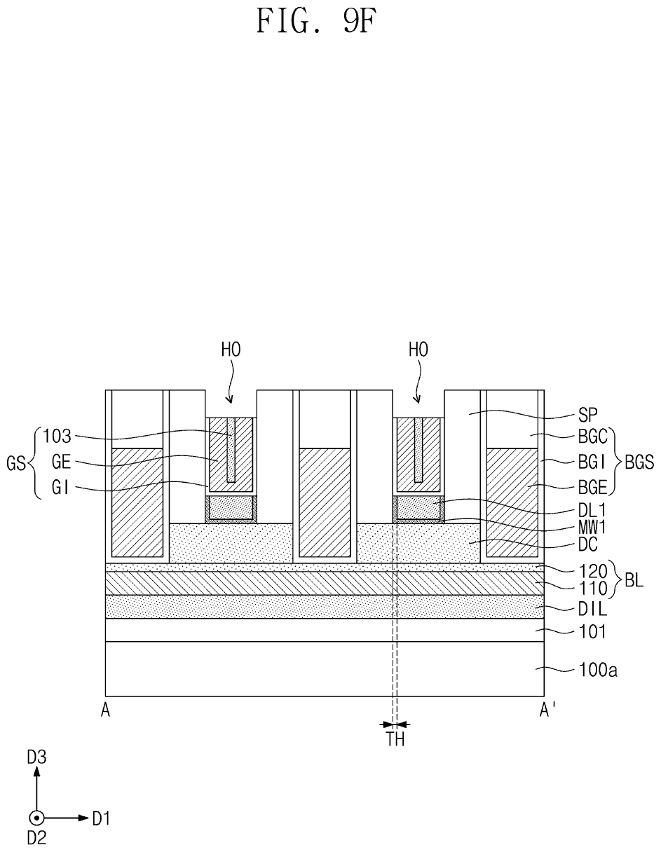

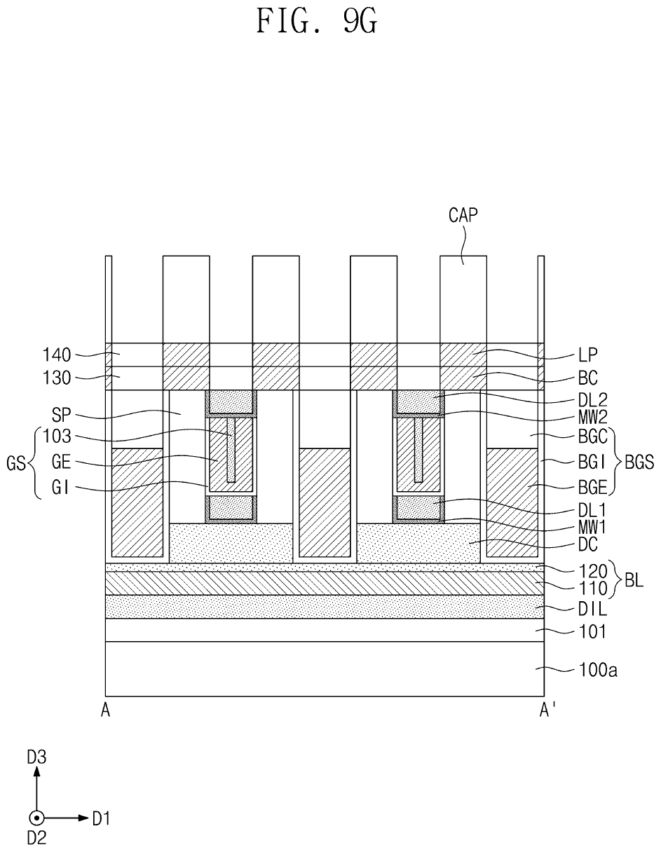

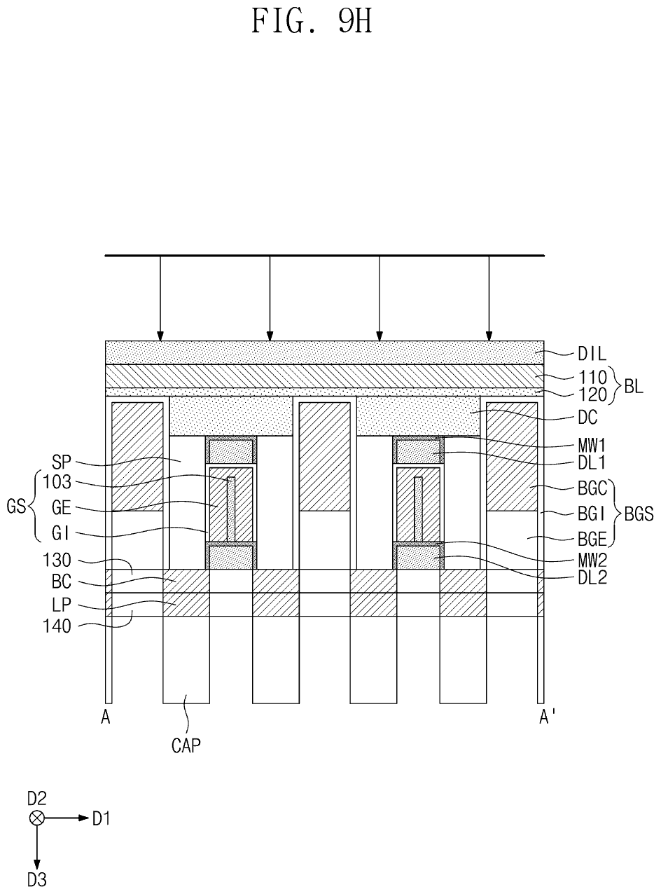

FIGS. 9A to 9H are cross-sectional views showing a manufacturing process of a semiconductor device according to some embodiments of the inventive concept. Specifically, FIGS. 9A to 9H are cross-sectional views showing the manufacturing process of the semiconductor device shown in the cross-section of FIG. 5.

Referring to FIG. 9A, a first dummy substrate 100a, a second dummy substrate 100b, a dummy insulating layer 101, a lower insulating layer DIL, a bit line BL, and bit line contact DC, which are between the first dummy substrate 100a and the second dummy substrate 100b, may be provided.

Specifically, the dummy insulating layer 101 may be formed on the first dummy substrate 100a. The dummy insulating layer 101 may include oxide. The lower insulating layer DIL and the bit line BL may be sequentially formed on the dummy insulating layer 101. Forming the bit line BL may include sequentially forming a metal pattern 110 and a polysilicon pattern 120 on the lower insulating layer DIL. Thereafter, the second dummy substrate 100b may be provided on the bit line BL.

Referring to FIG. 9B, a plurality of back gate structures BGS may be formed on the bit line BL. Specifically, the second dummy substrate 100b and the bit line contact DC may be etched until an upper surface of the polysilicon pattern 120 is exposed to form a plurality of back gate holes or openings (not shown). A back gate insulating pattern BGI may be formed on lower and side surfaces of the back gate hole (not shown). A back gate electrode BGE and a back gate capping pattern BGC may be sequentially formed in the remaining regions excluding the region where the back gate insulating pattern BGI is formed in the back gate hole (not shown).

Referring to FIG. 9C, a plurality of gate holes or openings HO may be formed on the bit line BL. The gate hole HO may define an region where the gate structure GS described in FIG. 5 will be formed. Forming the gate hole HO may include etching the second dummy substrate 100b until an upper surface of the bit line contact DC is exposed. As the gate holes HO are formed, a plurality of vertical channel patterns SP may be formed from the second dummy substrate 100b with the gate holes HO therebetween.

Referring to FIG. 9D, a first work function adjustment pattern MW1 and a first dielectric pattern DL1 surrounded by the first work function adjustment pattern MW1 may be formed on the bit line contact DC. Forming the first work function adjustment pattern MW1 and the first dielectric pattern DL1 may include forming a first adjustment layer (not shown) that covers lower and side surfaces of the gate hole HO and a first dielectric layer (not shown) that fills the inside of the first adjustment layer (not shown) and performing an etch-back process on the first adjustment layer (not shown) and the first dielectric layer (not shown). As the etch-back process is performed, upper regions of the first adjustment layer (not shown) and the first dielectric layer (not shown) may be removed. As a result, the first work function adjustment pattern MW1 and the first dielectric pattern DL1 may be formed from the first adjustment layer (not shown) and the first dielectric layer (not shown), respectively.

Referring to FIG. 9E, a gate insulating layer GIL may be formed inside the gate hole HO. Specifically, the gate insulating layer GIL may be formed on side and lower surfaces of the remaining portion of the gate hole HO excluding the region where the first work function adjustment pattern MW1 and the first dielectric pattern DLI are formed. The gate insulating layer GIL may be formed by a physical vapor deposition process, a chemical vapor deposition process, or an atomic layer deposition process.

Referring to FIG. 9F, a gate structure GS may be formed on the first work function adjustment pattern MW1 and the first dielectric pattern DL1. Forming the gate structure GS may include forming a gate electrode layer (not shown) filling the gate hole HO, performing an etch-back process on the gate insulating layer GIL and gate electrode layer (not shown) to form the gate insulating pattern GI and the gate electrode GE, and forming a gate dielectric layer 103 in the gate electrode GE. As the etch-back process is performed, an upper region of the gate electrode layer (not shown) and the gate insulating layer (GIL) may be removed. As a result, the gate electrode GE and the gate insulating pattern GI may be formed from the gate electrode layer (not shown) and the gate insulating layer GIL, respectively.

Referring to FIG. 9G, a second work function adjustment pattern MW2 and a second dielectric pattern DL2 may be sequentially formed on the gate structure GS. The second work function adjustment pattern MW2 and the second dielectric pattern DL2 may be formed through a process substantially similar to that of forming the first work function adjustment pattern MW1 and the first dielectric pattern DLI in FIG. 9D.

A first upper insulating layer 130 may be formed on the back gate structure BGS, the gate structure GS, and the vertical channel pattern SP. A portion of the first upper insulating layer 130 may be removed to expose an upper surface of the vertical channel pattern SP. A storage node contact BC may be formed on the upper surface of the vertical channel pattern SP.

A second upper insulating layer 140 may be formed on the first upper insulating layer 130. A portion of the second upper insulating layer 140 may be removed to expose an upper surface of the storage node contact BC. A landing pad LP may be formed on the upper surface of the storage node contact BC. Afterwards, a capacitor CAP may be formed on the landing pad LP.

Referring to FIG. 9H, the device formed in FIG. 9G may be flipped to expose a lower surface of the first dummy substrate 100a. Thereafter, the first dummy substrate 100a and the dummy insulating layer 101 may be removed. Removing the first dummy substrate 100a and the dummy insulating layer 101 may be performed through back grinding and chemical and mechanical polishing processes. As the first dummy substrate 100a and the dummy insulating layer 101 are removed, the lower surface of the lower insulating layer DIL may be exposed.

Afterwards, although not shown, the device is flipped again and the substrate SUB and peripheral circuit insulating layer PIL described in FIG. 2 may be bonded to the lower insulating layer DIL through a wafer bonding process, thereby completing the semiconductor device shown in FIG. 5.

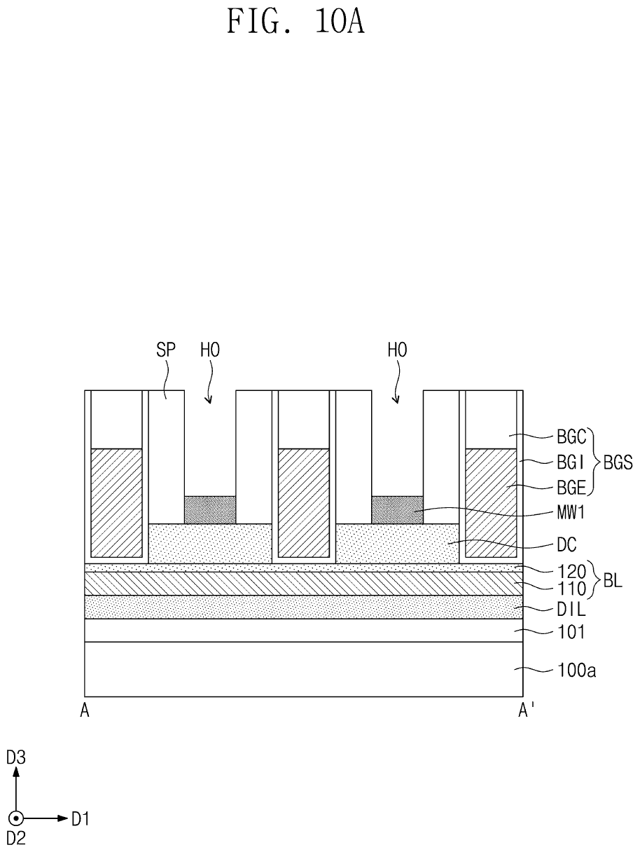

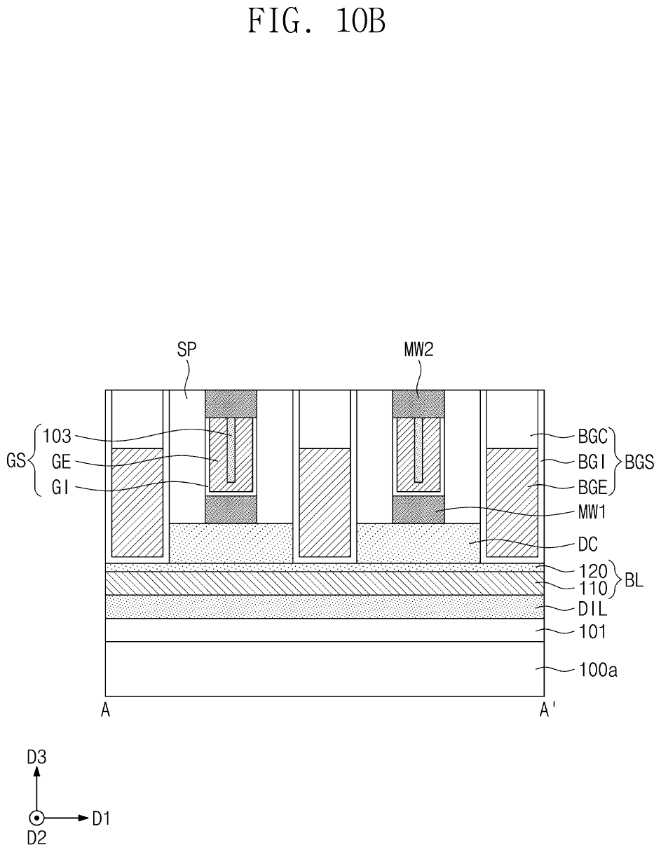

FIGS. 10A and 10B are cross-sectional views showing portion of a manufacturing

process of a semiconductor device according to some embodiments of the inventive concept. Specifically, FIGS. 10A and 10B are cross-sectional views showing portion of the manufacturing process of the semiconductor device shown in the cross-section of FIG. 7.

Referring to FIGS. 9A, 9B, 9C, and 10A, the first work function adjustment pattern MW1 may be formed in the gate hole HO. Forming the first work function adjustment pattern MW1 may include forming a first adjustment layer (not shown) filling the inside of the gate hole HO and performing an etch-back process on the first adjustment layer (not shown). As the etch-back process is performed, an upper region of the first adjustment layer (not shown) may be removed. As a result, the first work function adjustment pattern MW1 may be formed from the first adjustment layer (not shown).

Referring to FIG. 10B, a gate structure GS may be formed on the first work function adjustment pattern MW1. Forming the gate structure GS may be substantially the same as that described in FIG. 9F.

A second work function adjustment pattern MW2 may be formed on the gate structure GS. The second work function adjustment pattern MW2 may fill the interior space of the gate hole HO excluding the first work function adjustment pattern MW1 and the gate structure GS.

Thereafter, the semiconductor device shown in FIG. 7 may be completed by performing a process similar to the process described in FIGS. 9G and 9H.

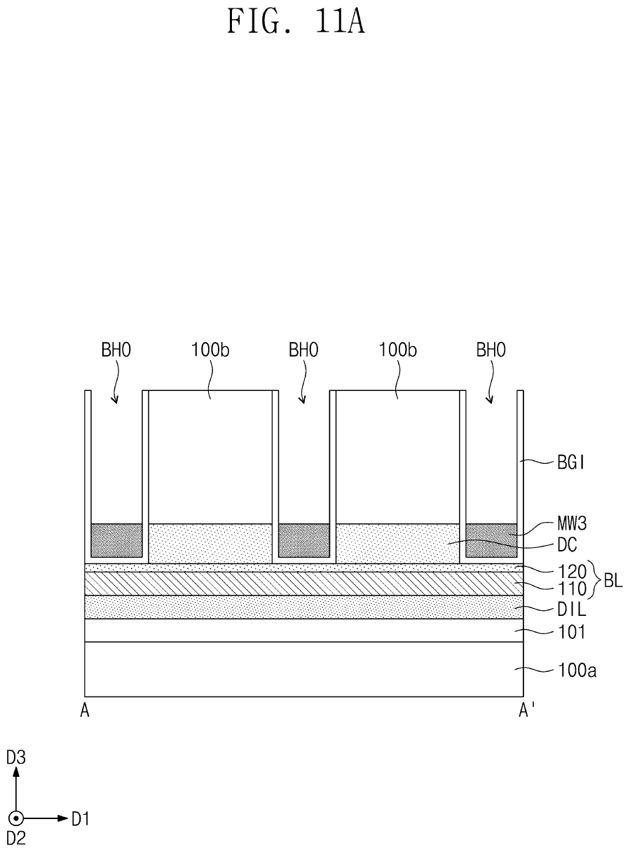

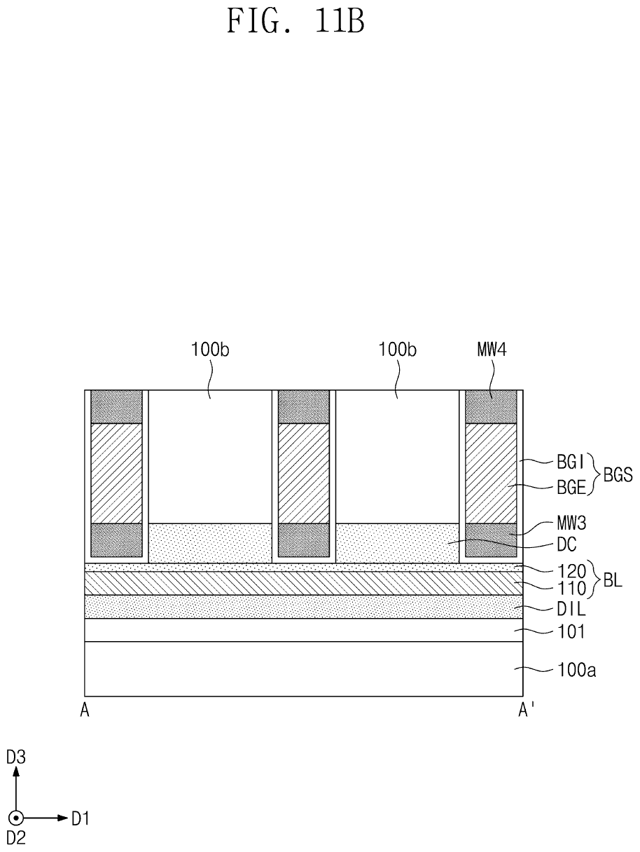

FIGS. 11A and 11B are cross-sectional views showing portion of a manufacturing process of a semiconductor device according to some embodiments of the inventive concept. Specifically, FIGS. 11A and 11B are cross-sectional views showing portion of the manufacturing process of the semiconductor device shown in the cross-section of FIG. 8.

Referring to FIGS. 9A, 9B, and 11A, the second dummy substrate 100b and the bit line contact DC may be etched until the upper surface of the polysilicon pattern 120 is exposed, to form a plurality of back gate holes BHO. A back gate insulating pattern BGI may be formed on lower and side surfaces of the back gate hole BHO.

Thereafter, a third work function adjustment pattern MW3 may be formed in the inner space of the back gate hole BHO excluding the back gate insulating pattern BGI. Forming the third work function adjustment pattern MW3 may include forming a third adjustment layer (not shown) that fills the inside of the back gate hole GHO and performing an etch-back process on the third adjustment layer (not shown). As the etch-back process is performed, an upper region of the third adjustment layer (not shown) may be removed. As a result, the third work function adjustment pattern MW3 may be formed from the third adjustment layer (not shown).

Referring to FIG. 11B, a back gate electrode BGE may be formed on the third work

function adjustment pattern MW3. Forming the back gate electrode BGE may include forming a back gate electrode layer (not shown) that fills the remaining region of the back gate hole BHO except for the region where the third work function adjustment pattern MW3 is formed, and performing an etch-back process on an electrode layer (not shown) on the back gate electrode layer (not shown) to form the back gate electrode BGE.

A fourth work function adjustment pattern MW4 may be formed on the back gate electrode BGE. The fourth work function adjustment pattern MW4 may be formed in the remaining region of the back gate hole BHO excluding the region where the third work function adjustment pattern MW3 and the back gate electrode BGE are formed.

Thereafter, the semiconductor device shown in FIG. 8 may be completed by performing a process similar to the process described in FIGS. 9C to 9H.

The semiconductor device according to the inventive concept may include work function adjustment patterns between the gate electrode and the bit line contact, and between the gate electrode and the storage node contact. The work function of the work function adjustment patterns (e.g., the third work function) may be a value between the values of the work function of the gate electrode (e.g., the second work function) and the work function of the bit line contact and/or the storage node contact (e.g., the first work function). Accordingly, the metal resistance between the gate electrode and the bit line contact and the metal resistance between the gate electrode and the storage node contact may be alleviated, and the leakage current of the gate electrode may be reduced. As a result, the electrical characteristics and reliability of semiconductor devices may be improved.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the scope of the inventive concept being indicated by the appended claims.

What is claimed is:

1. A semiconductor device comprising:
a substrate;
a bit line extending in a first direction on the substrate;
a vertical channel pattern on the bit line;
a gate electrode adjacent to the vertical channel pattern in the first direction;
a first work function adjustment pattern on the gate electrode; and
a first contact on the vertical channel pattern,
wherein the first work function adjustment pattern is adjacent to one end of the vertical channel pattern in the first direction, and
wherein the first work function adjustment pattern includes a metal material different from that of the gate electrode.

2. The semiconductor device of claim 1, wherein the first work function adjustment pattern is on a lower portion of the gate electrode,
wherein the semiconductor device further includes a second work function adjustment pattern on an upper portion of the gate electrode that is opposite the lower portion,
wherein the first and second work function adjustment patterns have respective work function values that are lower than that of the gate electrode.

3. The semiconductor device of claim 2, wherein the first work function adjustment pattern and the second work function adjustment pattern include at least one of aluminum oxide or lanthanum oxide.

4. The semiconductor device of claim 2, wherein the first work function adjustment pattern and the second work function adjustment pattern include polysilicon doped with impurities.

5. The semiconductor device of claim 2, wherein the first contact is on a lower surface of the vertical channel pattern and contacts the first work function adjustment pattern on the bit line,
wherein the semiconductor device further includes a second contact on an upper surface of the vertical channel pattern that is opposite the lower surface.

6. The semiconductor device of claim 5, wherein the first contact is a bit line contact that electrically connects the vertical channel pattern to the bit line,
wherein the second contact is a storage node contact that electrically connects the vertical channel pattern to a storage node of the semiconductor device, and
wherein the respective work function values of the first and second work function adjustment patterns are higher than that of the bit line contact and/or the storage node contact.

7. The semiconductor device of claim 2, further comprising:
a first dielectric pattern on the first work function adjustment pattern;
a second dielectric pattern on the second work function adjustment pattern; and
a gate insulating pattern extending around the gate electrode.

8. The semiconductor device of claim 7, wherein a lower portion of the gate insulating pattern is in contact with the first work function adjustment pattern and the first dielectric pattern, and
wherein an upper portion of the gate insulating pattern, which is opposite the lower portion, is in contact with the second work function adjustment pattern.

9. The semiconductor device of claim 7, wherein the first work function adjustment pattern and the second work function adjustment pattern have a thickness of about 3 Angstroms (Å) to about 10 Å.

10. The semiconductor device of claim 1, further comprising:
a back gate structure extending into the bit line contact on the bit line,
wherein the back gate structure includes a back gate electrode, and
wherein the vertical channel pattern is provided on one side of the back gate structure.

11. The semiconductor device of claim 10, further comprising:
a third work function adjustment pattern on a lower surface of the back gate electrode and a fourth work function adjustment pattern on an upper surface of the back gate electrode that is opposite the lower surface.

12. The semiconductor device of claim 11, wherein each of the third work function adjustment pattern and the fourth work function adjustment pattern includes polysilicon doped with an impurity.

13. The semiconductor device of claim 11, wherein the back gate electrode has a first height in a second direction perpendicular to the upper surface of the substrate,
wherein each of the third work function adjustment pattern and the fourth work function adjustment pattern has a second height in the second direction, and
wherein the first height is about 3 to about 5 times the second height.

14. The semiconductor device of claim 13, wherein the first height is about 20 nm to about 40 nm, and
wherein the second height is about 100 nm to about 120 nm.

15. A semiconductor device comprising:
a substrate;
a bit line on the substrate;
a bit line contact on the bit line;
vertical channel patterns and a gate structure on the bit line, wherein the gate structure is between the vertical channel patterns;
a first work function adjustment pattern on the gate structure; and
a storage node contact on the vertical channel pattern,
wherein the gate structure includes a gate electrode,
wherein the first work function adjustment pattern has a first work function,
wherein the bit line contact and the storage node contact have a second work function,
wherein the gate electrode has a third work function, and
wherein a value of the first work function is between those of the second work function and the third work function.

16. The semiconductor device of claim 15, wherein the first work function adjustment pattern is on a lower portion of the gate structure,
wherein the semiconductor device further includes a second work function adjustment pattern on an upper portion of the gate structure that is opposite the lower portion, and
wherein the gate structure includes a gate insulating pattern extending around the gate electrode.

17. The semiconductor device of claim 16, wherein one sidewall of the vertical channel patterns is in contact with the first work function adjustment pattern, the gate insulating pattern, and the second work function adjustment pattern.

18. A semiconductor device comprising:
a substrate;
a bit line on the substrate;
a bit line contact on the bit line;
a gate structure, a work function adjustment pattern and vertical channel patterns on the bit line contact, the work function adjustment pattern including a first work function adjustment pattern on a lower portion of the gate structure and a second work function adjustment pattern on an upper portion of the gate structure that is opposite the lower portion;
a back gate structure extending into the bit line contact on the bit line;
a storage node contact on one of the vertical channel patterns;
a landing pad on the storage node contact; and
a capacitor on the landing pad,
wherein the gate structure includes a gate electrode,
wherein the first work function adjustment pattern and the second work function adjustment pattern are adjacent to the bit line contact and the storage node contact, respectively,
wherein the work function adjustment pattern has a work function of about 4.15 eV to about 4.3 eV,
wherein the bit line contact and the storage node contact have a work function of about 3.9 eV to about 4.1 eV, and
wherein the gate electrode has a work function of about 4.4 eV to about 4.6 eV.

19. The semiconductor device of claim 18, wherein the work function adjustment pattern includes polysilicon doped with impurities.

20. The semiconductor device of claim 19, wherein upper surfaces of the vertical channel patterns and an upper surface of the second work function adjustment pattern are substantially coplanar.
